(19) United States
(12) Patent Application Publication
(10) Pub. No.: US 2020/0281086 A1
(43) Pub. Date: Sep. 3, 2020

(54) PULL-OUT AIDING DEVICE

(71) Applicant: FIVETECH TECHNOLOGY INC., New Taipei City (TW)

(72) Inventor: TING-JUI WANG, NEW TAIPEI CITY (TW)

(21) Appl. No.: 16/879,022

(22) Filed: May 20, 2020

Related U.S. Application Data
(63) Continuation-in-part of application No. 15/990,867, filed on May 29, 2018.
Application No. 15/990,867 is a division of application No. 15/381,589, filed on Dec. 16, 2016, now abandoned.

(30) Foreign Application Priority Data
Dec. 25, 2015 (TW) 104220885

(51) Int. Cl. H05K 7/14; G11B 33/12; G06F 1/18

(52) U.S. Cl. CPC H05K 7/1402; G06F 1/187; G11B 33/124

(57) ABSTRACT

A pull-out aiding device includes a pulling component and a gripping component. The pulling component includes a first pivotal connection portion and a corresponding portion. The corresponding portion abuts against a target. The gripping component includes a second pivotal connection portion and an operating portion. The second pivotal connection portion is pivotally connected to the first pivotal connection portion, such that the gripping component rotates about the second pivotal connection portion.

### CROSS-REFERENCE TO RELATED APPLICATION

This application is a continuation-in-part patent application of U.S. application Ser. No. 15/990,867 filed on May 29, 2018, which is a divisional application of U.S. application Ser. No. 15/381,589 filed on Dec. 16, 2016, the entire contents both of which are hereby incorporated by reference for which priority is claimed under 35 U.S.C. § 120, which claims priority to Taiwanese Patent Application No(s). 104220885 filed on Dec. 25, 2015.

### BACKGROUND OF THE INVENTION

### 1. Field of the Invention

The present disclosure relates to a pull-out aiding device mountable on a chassis, housing, casing or the like and adapted to facilitate pushing and pulling a target, such as a hard disk drive, received therein.

### 2. Description of the Related Art

A conventional chassis usually comes with an unloading mechanism (also known as disengaging mechanism). The purpose of the unloading mechanism is to separate a hard disk drive or circuit board from a port disposed in the chassis. When a user rotates the unloading mechanism, the hard disk drive or circuit board is pushed and thus moved to cause its separation from the port. However, the function of the unloading mechanism of the conventional chassis is restricted to moving the hard disk drive or circuit board for a short distance (typically 3-5 mm). As a result, the prior art lacks ease of use.

### BRIEF SUMMARY OF THE INVENTION

An objective of the present disclosure is to provide a pull-out aiding device which is labor-saving and is simple and convenient to operate.

To achieve at least the above objective, the present disclosure provides a pull-out aiding device mountable on an object. The pull-out aiding device comprises a pulling component and a gripping component. The pulling component is movably or pullably coupled to a first lateral plate. The pulling component comprises a first pivotal connection portion, a corresponding portion and a corresponding obstructing portion. The gripping component comprises a second pivotal connection portion, an operating portion and an obstructing portion. The second pivotal connection portion is pivotally connected to the first pivotal connection portion, such that the gripping component rotates about the second pivotal connection portion. The obstructing portion of the gripping component is obstructed by the corresponding obstructing portion of the pulling component to limit the included angle between the pulling component and the gripping component.

The present disclosure further provides a pull-out aiding device mountable on an object. The pull-out aiding device comprises a pulling component and a gripping component. The pulling component is movably or pullably coupled to a first lateral plate. The pulling component comprises a first pivotal connection portion, a corresponding portion and a corresponding obstructing portion. The gripping component comprises a second pivotal connection portion, an operating portion and an obstructing portion. The second pivotal connection portion is pivotally connected to the first pivotal connection portion, such that the gripping component rotates about the second pivotal connection portion. The obstructing portion of the gripping component is obstructed by the corresponding obstructing portion of the pulling component to limit the included angle between the pulling component and the gripping component. The included angle is 90 degrees or ranges from 70 degrees to 110 degrees.

The present disclosure further provides a pull-out aiding device mountable on an object. The pull-out aiding device comprises a pulling component and a gripping component. The pulling component is movably or pullably coupled to a first lateral plate. The pulling component comprises a first pivotal connection portion and a corresponding portion. The first lateral plate has a corresponding blocking portion. The gripping component comprises a second pivotal connection portion, an operating portion, a blocking portion and a return hook portion. The second pivotal connection portion is pivotally connected to the first pivotal connection portion, such that the gripping component rotates about the second pivotal connection portion. The obstructing portion of the gripping component is obstructed by the corresponding obstructing portion of the pulling component to limit an included angle between the pulling component and the gripping component. The blocking portion of the gripping component and the corresponding blocking portion blocking of the first lateral plate engage with each other to ensure that the return hook portion can engage with the entry position of the first lateral plate only if the gripping component reaches the return hook portion to engage with an entry position of the first lateral plate.

The present disclosure further provides a pull-out aiding device mountable on an object. The pull-out aiding device comprises: a pulling component movably or pullably coupled to a first lateral plate and comprising a first pivotal connection portion and a corresponding portion, wherein the first lateral plate has a corresponding blocking portion; and a gripping component comprising a second pivotal connection portion, an operating portion and a blocking portion. The second pivotal connection portion is pivotally connected to the first pivotal connection portion, such that the gripping component rotates about the second pivotal connection portion. The blocking portion of the gripping component and the corresponding blocking portion of the first lateral plate engage with each other to ensure that the blocking portion can enter an entry position of the first lateral plate only if the gripping component reaches a non-blocking position of the first lateral plate.

The present disclosure further provides a pull-out aiding device mountable on an object. The pull-out aiding device comprises a pulling component and a gripping component. The pulling component is movably or pullably coupled to a first lateral plate. The pulling component comprises a first pivotal connection portion and a corresponding portion. The gripping component comprises a second pivotal connection portion, an operating portion and a guiding portion. The second pivotal connection portion is pivotally connected to the first pivotal connection portion, such that the gripping component rotates about the second pivotal connection portion. Alternatively, the gripping component comprises a second lateral plate having a corresponding guiding portion. The corresponding guiding portion guides the gripping component resilient in engaging with an entry position of the second lateral plate corresponding.

Regarding the pull-out aiding device, the guiding portion or the corresponding guiding portion is an oblique surface, curved surface, arcuate surface, stepped surface or flat surface.

Regarding the pull-out aiding device, the entry position is a raised portion or dented portion.

Regarding the pull-out aiding device, the obstructing portion or the corresponding obstructing portion is a flat surface portion, oblique surface portion, arcuate surface portion, curved surface portion, stepped portion, engaging portion, hook portion, raised portion or dented portion.

Therefore, the present disclosure provides a pull-out aiding device and a board module, which are adapted to facilitate pushing and pulling a target received therein, are labor-saving, and are simple and convenient to operate.

### BRIEF DESCRIPTION OF THE DRAWINGS

FIG. 1 is a schematic view of a pull-out aiding device and target according to the first embodiment of the present disclosure.

FIG. 2 is a schematic view showing that a gripping component of the pull-out aiding device in the first embodiment of the present disclosure is located at a withdrawn position.

FIG. 3 is an enlarged view of portion A in FIG. 1.

FIG. 4 is a partial perspective view of the pull-out aiding device according to the first embodiment of the present disclosure.

FIG. 5 is another partial perspective view of the pull-out aiding device according to the first embodiment of the present disclosure.

FIG. 6 is a schematic view showing that a first limiting unit and a second limiting unit are coupled together according to another embodiment of the present disclosure.

FIG. 7 is an exploded view showing the first limiting unit and the second limiting unit according to another embodiment of the present disclosure.

FIG. 8 is a lateral view of the first limiting unit and the second limiting unit according to another embodiment of the present disclosure.

FIG. 9 is a schematic view of how to operate the first limiting unit and the second limiting unit of FIG. 6.

FIG. 10 is another schematic view of how to operate the first limiting unit and the second limiting unit of FIG. 6.

FIG. 11 is a schematic view showing that a pulling component comprises a bend segment.

FIG. 12 is a schematic view of a board module according to the second embodiment of the present disclosure.

FIG. 13 is another schematic view of the board module according to the second embodiment of the present disclosure.

FIG. 14 is a perspective view of the pull-out aiding device according to the third preferred embodiment of the present disclosure.

FIG. 15 is an exploded view of the pull-out aiding device according to the third preferred embodiment of the present disclosure.

FIG. 16 is a front cross-sectional view of the pull-out aiding device according to the third preferred embodiment of the present disclosure.

FIG. 17 is a cross-sectional view of the pull-out aiding device taken along line A-A according to the third preferred embodiment of the present disclosure.

FIG. 18 is a schematic view of a manually-manipulatable portion of the pull-out aiding device according to the third preferred embodiment of the present disclosure.

FIG. 19 is another perspective view of the pull-out aiding device according to the third preferred embodiment of the present disclosure.

FIG. 20 is another exploded view of the pull-out aiding device according to the third preferred embodiment of the present disclosure.

FIG. 21 is another front cross-sectional view the pull-out aiding device according to the third preferred embodiment of the present disclosure.

FIG. 22 is a schematic view of an abutting portion of the pull-out aiding device according to the third preferred embodiment of the present disclosure.

FIG. 23 is a front cross-sectional view of the pull-out aiding device according to the fourth preferred embodiment of the present disclosure.

FIG. 24 is a perspective view of the pull-out aiding device according to the fourth preferred embodiment of the present disclosure.

FIG. 25 is a schematic view of a leaf spring and an engaging portion of the pull-out aiding device according to the fourth preferred embodiment of the present disclosure.

FIG. 26A is a schematic view of how to operate the pull-out aiding device according to the fourth preferred embodiment of the present disclosure.

FIG. 26B is a schematic view of how to operate the pull-out aiding device according to the fourth preferred embodiment of the present disclosure.

FIG. 26C is a schematic view of how to operate the pull-out aiding device according to the fourth preferred embodiment of the present disclosure.

FIG. 26D is a schematic view of how to operate the pull-out aiding device according to the fourth preferred embodiment of the present disclosure.

FIG. 27A is a schematic view of how to operate the pull-out aiding device according to the fourth preferred embodiment of the present disclosure.

FIG. 27B is a schematic view of how to operate the pull-out aiding device according to the fourth preferred embodiment of the present disclosure.

FIG. 27C is a schematic view of how to operate the pull-out aiding device according to the fourth preferred embodiment of the present disclosure.

FIG. 27D is a schematic view of how to operate the pull-out aiding device according to the fourth preferred embodiment of the present disclosure.

FIG. 28 is a schematic view of the pull-out aiding device according to the fifth preferred embodiment of the present disclosure.

FIG. 29 is a schematic view of the pull-out aiding device according to the sixth preferred embodiment of the present disclosure.

FIG. 30 is a schematic view of the pull-out aiding device according to the seventh preferred embodiment of the present disclosure.

FIG. 31 is a schematic view of the pull-out aiding device according to the eighth preferred embodiment of the present disclosure.

FIG. 32 is a schematic view of the pull-out aiding device according to the eighth preferred embodiment of the present disclosure.

FIG. 33 is a schematic view of the pull-out aiding device according to the ninth preferred embodiment of the present disclosure.

FIG. 34 is a schematic view of the pull-out aiding device according to the ninth preferred embodiment of the present disclosure.

FIG. 35 is a schematic view of the pull-out aiding device according to the tenth preferred embodiment of the present disclosure.

FIG. 36 is a schematic view of the pull-out aiding device according to the tenth preferred embodiment of the present disclosure.

FIG. 37 is a schematic view of the pull-out aiding device according to the eleventh preferred embodiment of the present disclosure.

FIG. 38 is a schematic view of the pull-out aiding device according to the twelfth preferred embodiment of the present disclosure.

FIG. 39 is a schematic view of the pull-out aiding device according to the thirteenth preferred embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

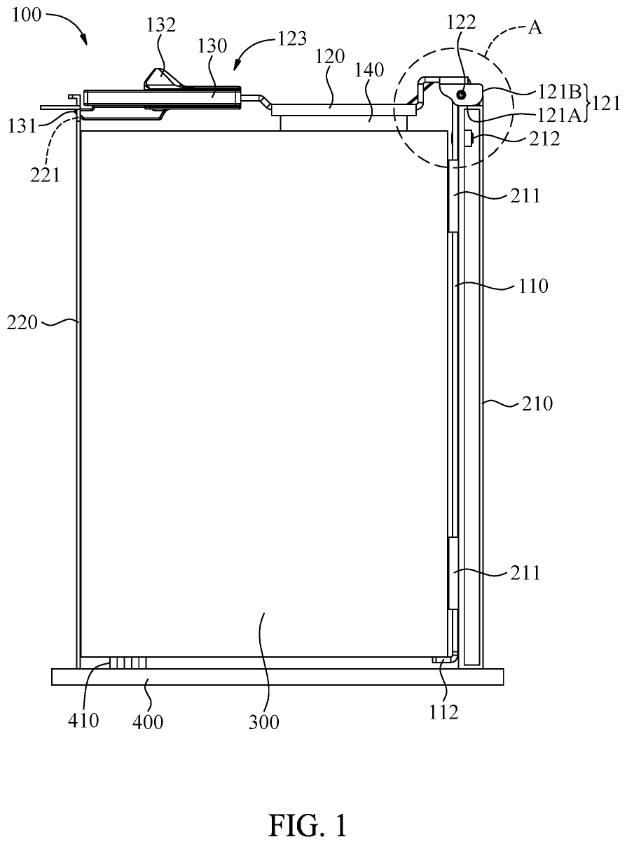

Referring to FIG. 1 through FIG. 3, the first embodiment of the present disclosure provides a pull-out aiding device 100 mountable on an object. The object comprises a first lateral plate 210 and an opposing second lateral plate 220. A target 300, such as a hard disk drive, memory, PCB (printed circuit board), casing, block or graphics card, is placed on the object. The object further comprises a top plate and a bottom plate (not shown) which are connected to the first lateral plate 210 and the second lateral plate 220. The first lateral plate 210, the second lateral plate 220, the top plate and the bottom plate jointly define a containing space for receiving the target 300 and an opening in communication with the containing space. The containing space has therein a circuit board 400. The circuit board 400 has thereon a plug port 410. The plug port 410 is plugged into a receptacle (not shown) of the target 300, such as a hard disk drive.

For instance, the object is a chassis, drawer, hole, groove, cover or board.

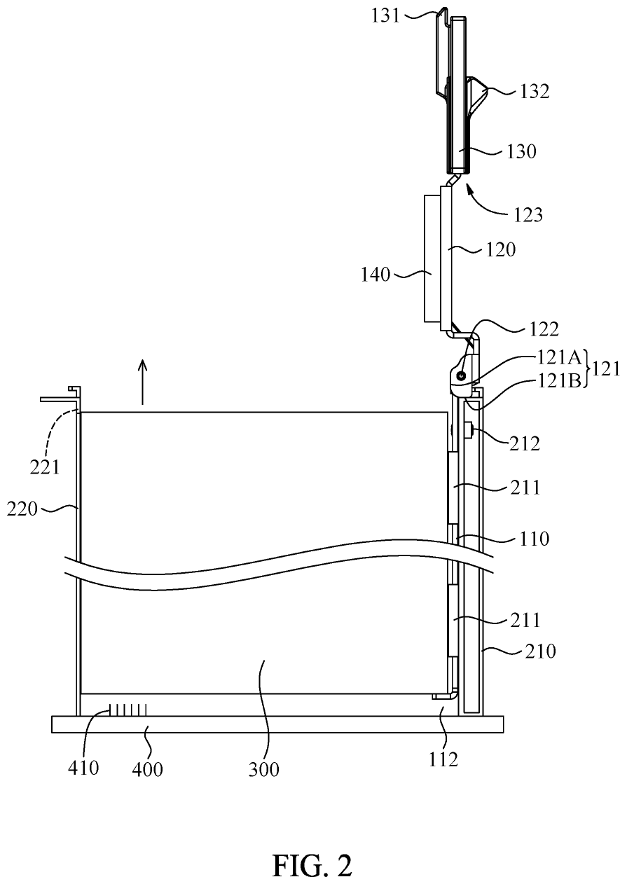

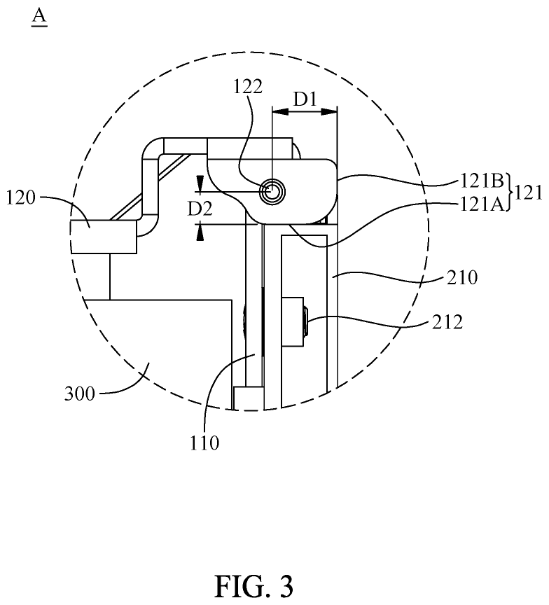

The pull-out aiding device 100 comprises a pulling component 110 and a gripping component 120. The pulling component 110 is movably coupled to the first lateral plate 210. The pulling component 110 comprises a first pivotal connection portion 111 and a corresponding portion 112 which are disposed at two opposite ends, respectively. The corresponding portion 112 abuts against the target 300. The gripping component 120 comprises an abutting portion 121, a second pivotal connection portion 122 and an operating portion 123. The second pivotal connection portion 122 is positioned proximate to the abutting portion 121 and pivotally connected to the first pivotal connection portion 111, such that the gripping component 120 rotates about the second pivotal connection portion and between a closed position (shown in FIG. 1) and a withdrawn position (shown in FIG. 2). The abutting portion 121 has a closed side 121A and a protruding side 121B. As shown in FIG. 3, distance D1 between the protruding side 121B and the second pivotal connection portion 122 is greater than distance D2 between the closed side 121A and the second pivotal connection portion 122, but the present disclosure is not limited thereto. In a variant embodiment, distance D1 between the protruding side 121B and the second pivotal connection portion 122 is equal to or less than distance D2 between the closed side 121A and the second pivotal connection portion 122.

Therefore, when the gripping component 120 is at closed position, the closed side 121A is adjacent to or is positioned proximate to the first lateral plate 210. By contrast, when the gripping component 120 is at withdrawn position, the protruding side 121B is adjacent to or is positioned proximate to the first lateral plate 210, and the corresponding portion 112 moves for a pull distance relative to the first lateral plate 210. The pull distance depends on distance D1 between the protruding side 121B and the second pivotal connection portion 122 and distance D2 between the closed side 121A and the second pivotal connection portion 122. For instance, the pull distance is 0.5 mm 500 mm.

In this embodiment, the gripping component 120 is substantially perpendicular to or not parallel to the first lateral plate 210 when the gripping component 120 is at closed position, and the gripping component 120 is substantially parallel to or not perpendicular to the first lateral plate 210 when the gripping component 120 is at withdrawn position.

As shown in FIG. 1 and FIG. 2, the corresponding portion 112 has an L-shaped arm for engaging with the bottom side of the target 300. Thus, when the pulling component 110 advances, it pushes the target 300. However, the corresponding portion 112 may be of any shape and thus provided in the form of a hook member, raised member, dented member, stepped member, flat surface member, arcuate surface member, curved surface member, engaging member, box, casing or sleeve.

In this embodiment, the first lateral plate 210 has a rail unit 211 facing the second lateral plate 220. The pulling component 110 is movably coupled to the rail unit 211, such that the pulling component 110 moves relative to the first lateral plate 210, away from the circuit board 400, and toward the object opening.

When the gripping component 120 is operated to rotatably switch from closed position to withdrawn position, not only does the pulling component 110 move outward because the distance between the protruding side 121B and the second pivotal connection portion 122 is greater than the distance between the closed side 121A and the second pivotal connection portion 122, but the target 300 is also pushed by the corresponding portion 112 to thereby separate from the plug port 410 and advance, thereby allowing the target 300 to move and protrude from the first lateral plate 210 and the second lateral plate 220. After that, the user keeps pulling the gripping component 120 for a distance, such that the target 300 protrudes further, thereby allowing the target 300 to be easily gripped by hand and removed from the object.

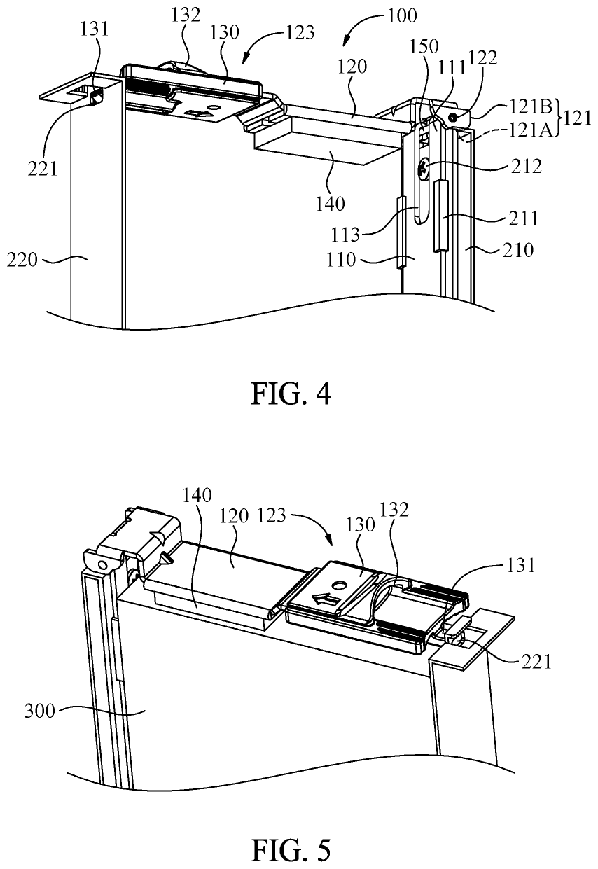

Referring to FIG. 4, the first pivotal connection portion 111 and the second pivotal connection portion 122 are pivotally coupled together by a shaft 150, but the present disclosure is not limited thereto. In a variant embodiment, the first pivotal connection portion 111 and the second pivotal connection portion 122 are coupled together by a hinge structure or engaged with each other by an engagement structure.

The pulling component 110 has a first limiting unit 113. When the gripping component 120 is located at withdrawn position, mutual interference and limitation occurs between the first limiting unit 113 and a second limiting unit 212 on the first lateral plate 210, thereby limiting the maximum length by which the pulling component 110 protrudes from the first lateral plate 210. In this embodiment, the first limiting unit 113 is an oblong hole. The second limiting unit 212 is a protruding member correspondingly received in the oblong hole. The protruding member is a screw, screw nut or rivet, which is fastened to the first lateral plate 210. The structural features of the first limiting unit 113 and the second limiting unit 212 are not limited thereto. In a variant embodiment, the first limiting unit 113 is a slot, and the second limiting unit 212 is correspondingly received in the hook member in the oblong hole. Alternatively, the second limiting unit 212 is an oblong hole or a slot, and the first limiting unit 113 is a protruding member or hook member correspondingly received in the oblong hole or slot.

The pull-out aiding device 100 comprises a damper 140. The damper 140 is disposed on a surface of the gripping component 120. The surface of the gripping component 120 faces the target 300. The damper 140 prevents the gripping component 120 from hitting the target 300. The damper 140 is, for example, a soft or resilient member, such as foam or sponge.

As shown in FIG. 4 and FIG. 5, the pull-out aiding device 100 comprises a movable sleeve 130. The movable sleeve 130 is movably coupled to the operating portion 123. The movable sleeve 130 has a latch 131 whereby the movable sleeve 130 is latched to a latching hole 221 of the second lateral plate 220 to ensure that the gripping component 120 stays at closed position. The movable sleeve 130 comprises a manual push portion 132 which protrudes from the movable sleeve 130.

In this embodiment, the pulling component 110 or the gripping component 120 is made of a metal or plastic.

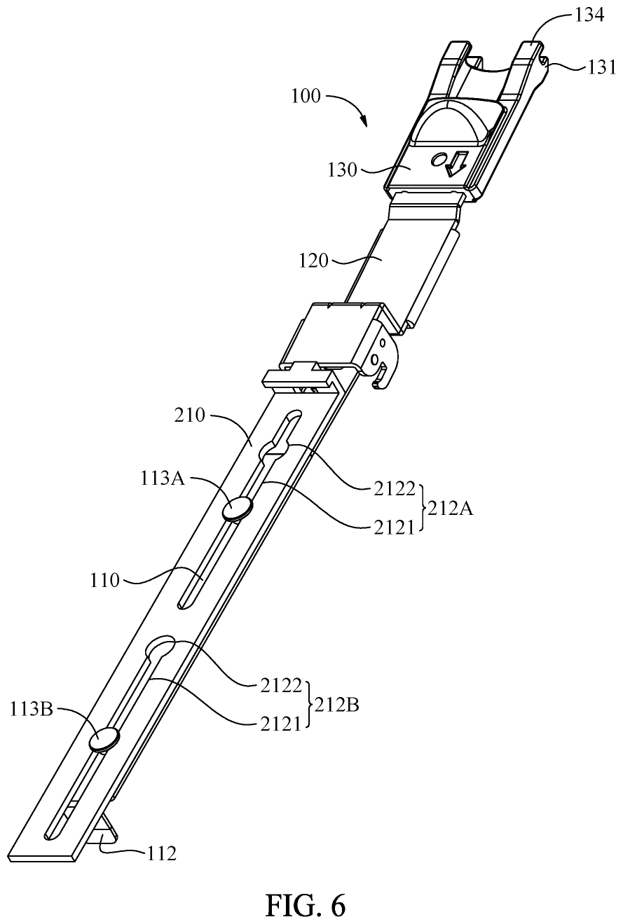

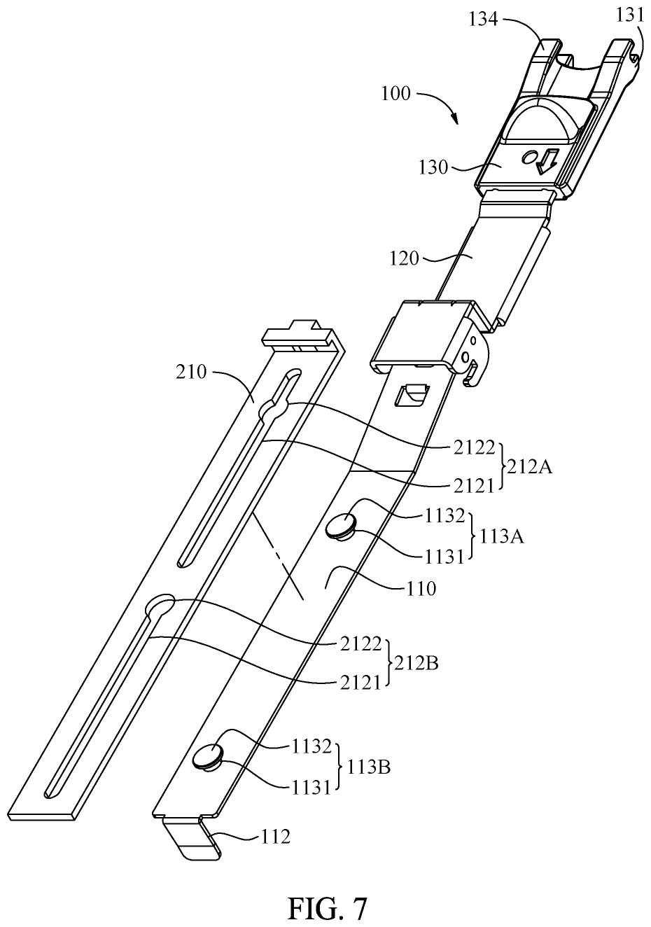

Referring to FIG. 6 and FIG. 7, which are schematic views of the first limiting unit 113 and the second limiting unit 212 according to another embodiment of the present disclosure. The first limiting unit 113 comprises two sliders 113A, 113B. The second limiting unit 212 comprises two quick-release rails 212A, 212B coupled to the sliders 113A, 113B, respectively. As shown in the diagrams, the sliders 113A, 113B slide along the quick-release rails 212A, 212B, respectively.

The movable sleeve 130 has latches 131 (two latches 131 in the diagrams). The second lateral plate 220 has thereon one or more latching holes 221 (not shown) which the latches 131 are latched to. The movable sleeve 130 further has two positioning-stopping portions 134 adapted to be stopped at the front edge of the second lateral plate 220, such that the movable sleeve 130 and the second lateral plate 220 are fitted to each other.

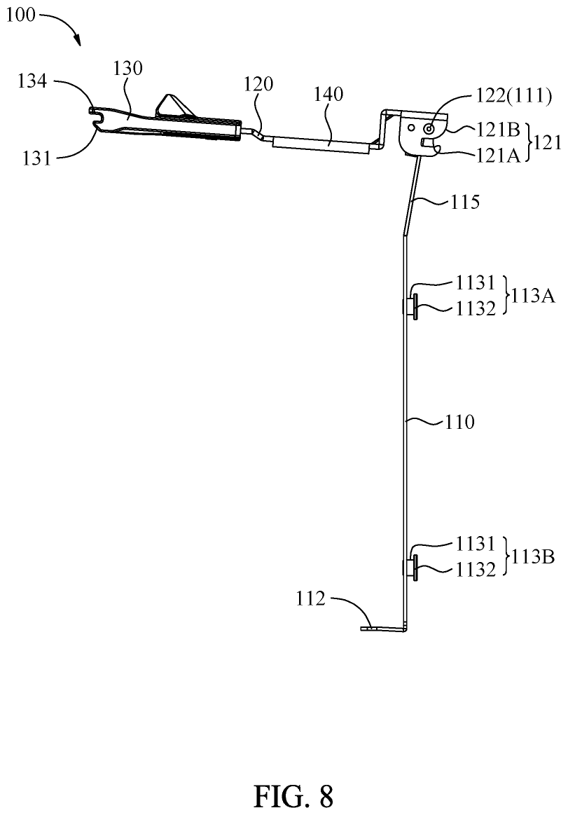

In this embodiment, as shown in FIGS. 6-8, the sliders 113A, 113B each have a cylindrical portion 1131 and a flange portion 1132 formed beside the cylindrical portion 1131. The quick-release rails 212A, 212B each have a rail portion 2121 and a quick-release hole portion 2122 which are in communication with each other. The cylindrical portions 1131 are movably disposed in the rail portions 2121, respectively. The diameter of the flange portions 1132 is greater than the diameter of the cylindrical portions 1131 and the width of the rail portions 2121, such that the sliders 113A, 113B can move within the rail portions 2121, respectively. The diameter of the flange portions 1132 is less than the diameter of the quick-release hole portion 2122; thus, when the sliders 113A, 113B move and become corresponding in position to the quick-release hole portions 2122, the flange portions 1132 penetrate the quick-release hole portions 2122, respectively, thereby allowing the pull-out aiding device to be demounted from the first lateral plate.

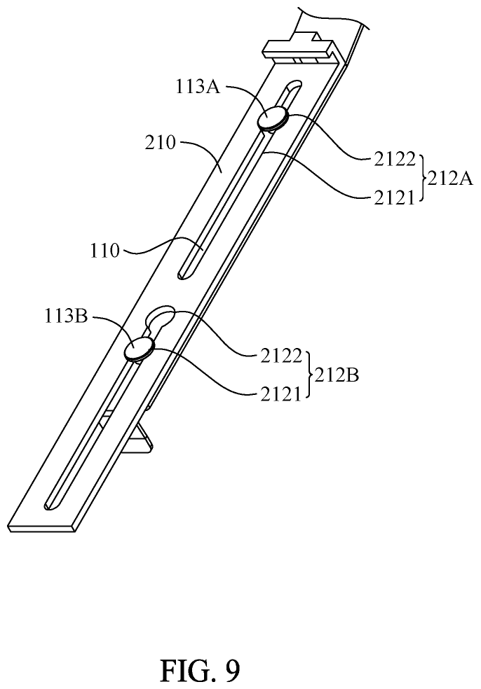

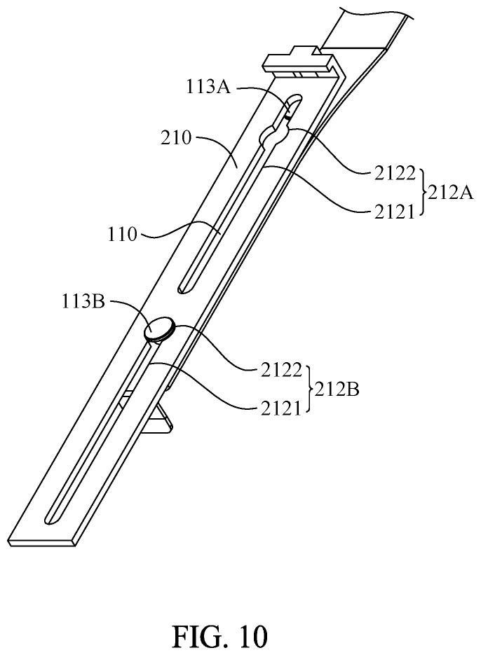

The distance between the two sliders 113A, 113B is greater than, less than or equal to the distance between the quick-release hole portions 2122 of the two quick-release rails 212A, 212B. Therefore, as shown in FIGS. 9 and 10, the two sliders 113A, 113B cannot be simultaneously separated from the two quick-release rails 212A, 212B, respectively. Preferably, the quick-release hole portions 2122 of the quick-release rails 212B are disposed at free ends of the rail portions 2121 (the free ends of the rail portions 2121 are positioned proximate to the second pivotal connection portion), and the quick-release hole portions 2122 of the quick-release rails 212A are spaced apart from the free ends of the rail portions 2121 by a distance. Thus, when the pulling component 110 is withdrawn relative to the first lateral plate 210, the sliders 113A reach the quick-release hole portions 2122 of the quick-release rails 212A, respectively, such that the flange portions 1132 of the sliders 113A exit the quick-release hole portions 2122 of the quick-release rails 212A, respectively. After that, the pulling component 110 is further withdrawn until the sliders 113B reach the quick-release hole portions 2122 of the quick-release rails 212B, respectively, and then the flange portions 1132 of the sliders 113B exit the quick-release hole portions 2122 of the quick-release rails 212B, respectively, thereby allowing the pull-out aiding device to be demounted from the first lateral plate.

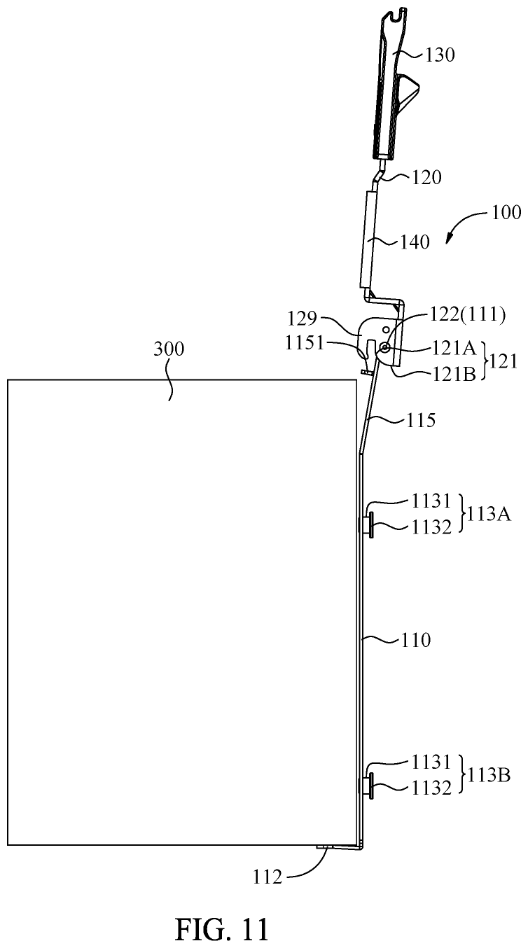

As shown in FIG. 11, the pulling component 110 comprises a bend segment 115. The bend segment 115 is positioned proximate to the first pivotal connection portion 111 and face the first lateral plate to bend by 2 to 90 degrees. The bend segment 115 has a protruding foolproof element 1151. The foolproof element 1151 ensures that the target 300 is correctly mounted in place. When the target 300 is correctly mounted in place, the corresponding portion 112 and the foolproof element 1151 press against the opposing bottom and top sides of the target 300, respectively. Thus, when the target 300 is not correctly mounted in place, the foolproof element 1151 interferes with the target 300 and thereby prevents the pull-out aiding device 100 from entering the object. When the pulling component 110 has not yet been withdrawn, the first lateral plate abuts against the bend segment 115, such that the bend segment 115 is parallel to the first lateral plate 210. It is only when the pulling component 110 is withdrawn relative to the first lateral plate 210 until the bend segment 115 is exposed that the gripping component 120, the first pivotal connection portion 111, the second pivotal connection portion 122, the bend segment 115 and the foolproof element 1151 bend outward relative to the target 300, such that the gripping component 120, the first pivotal connection portion 111, the second pivotal connection portion 122, the bend segment 115 and the foolproof element 1151 are unlikely to hinder the removal of the target 300, thereby enhancing ease of use.

The gripping component 120 is entirely made of plastic. The gripping component 120 has a hollowed-out opening whereby the target 300 is visible from outside.

Referring to FIG. 6, the movable sleeve 130 has two latches 131 and two positioning-stopping portions 134 which are stopped at the front edge of the second lateral plate 220, such that the movable sleeve 130 and the second lateral plate 220 are fitted to each other. In this embodiment, the movable sleeve 130 is connected to the operating portion 123 by compression springs.

Referring to FIG. 4, a resilient element is fitted around the shaft 150 between the first pivotal connection portion 111 of the pulling component 110 and the second pivotal connection portion 122 of the gripping component 120. the resilient element resiliently abuts against the pulling component 110 and the gripping component 120, such that the gripping component 120 undergoes automatic rotation and position restoration after being opened. The resilient element is a helical spring, torsion spring, resilient cylinder or leaf spring.

The gripping component 120 has a return hook portion 129. The return hook portion 129 is formed at one end (shown in FIG. 3) of the gripping component 120, wherein the second pivotal connection portion 122 is formed at the end (shown in FIG. 3) of the gripping component 120. The second lateral plate 220 has a return engaging hole. When the gripping component 120 is closed, the return hook portion 129 engages with the return engaging hole.

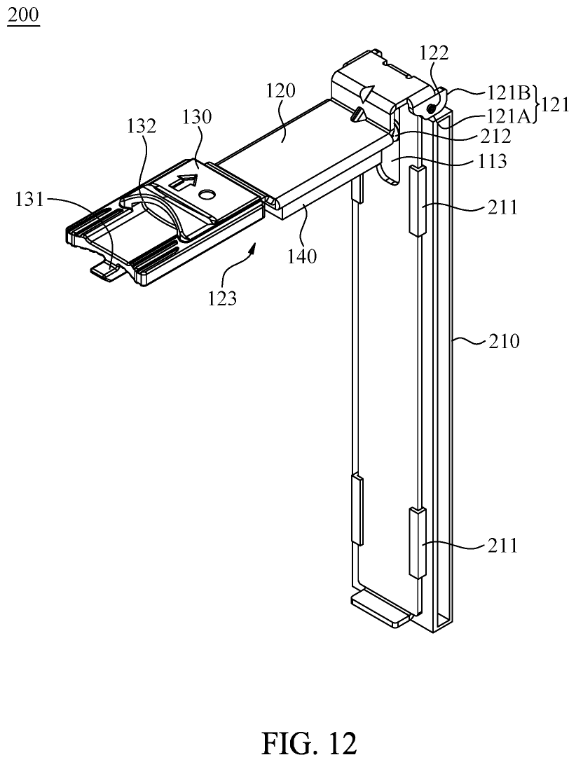

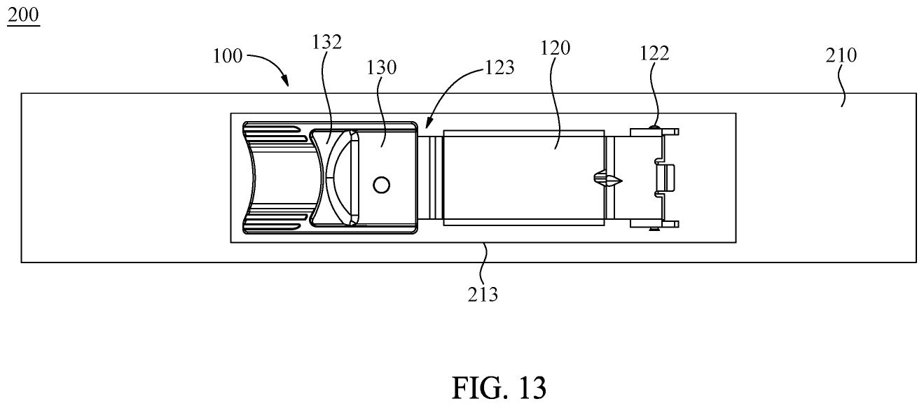

Referring to FIG. 12 and FIG. 13, there are shown schematic views of a board module 200 capable of facilitating pulling according to the second embodiment of the present disclosure.

Referring to FIG. 12, the board module 200 comprises a first lateral plate 210 and the pull-out aiding device 100 of the first embodiment. The pulling component 110 of the pull-out aiding device 100 is movably coupled to the first lateral plate 210.

Referring to FIG. 13, the board module 200 comprises a first lateral plate 210 and the pull-out aiding device 100 of the second embodiment. The pulling component 110 of the pull-out aiding device 100 is movably coupled to the first lateral plate 210. In this aspect, the first lateral plate 210 comprises a receiving recess 213. The pulling component 110 is received in the receiving recess 213.

In the second embodiment of the present disclosure, the pull-out aiding device 100 and the board module 200 facilitate taking out a target received therein and thus are labor-saving, and are simple and convenient to operate.

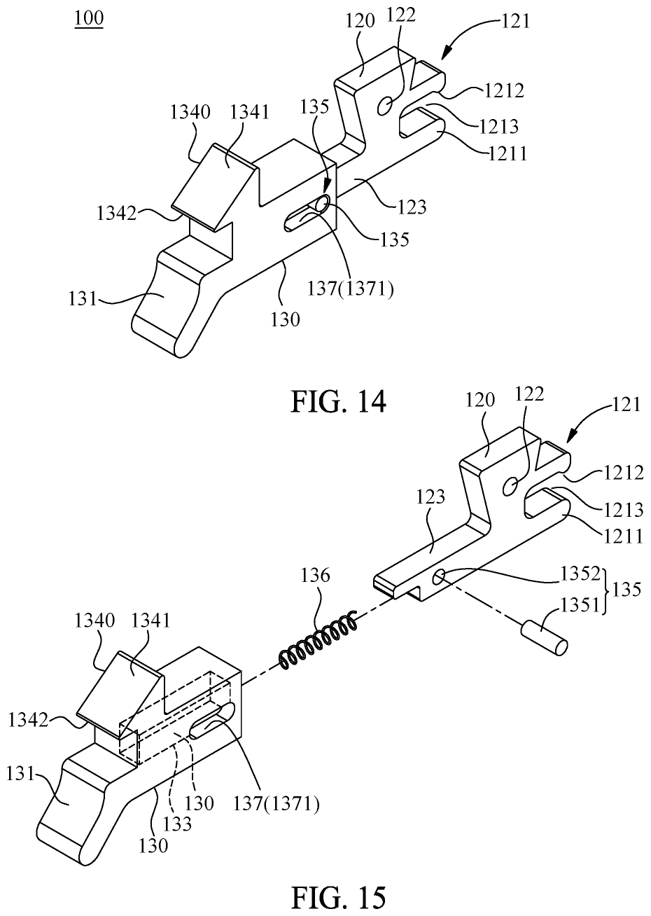

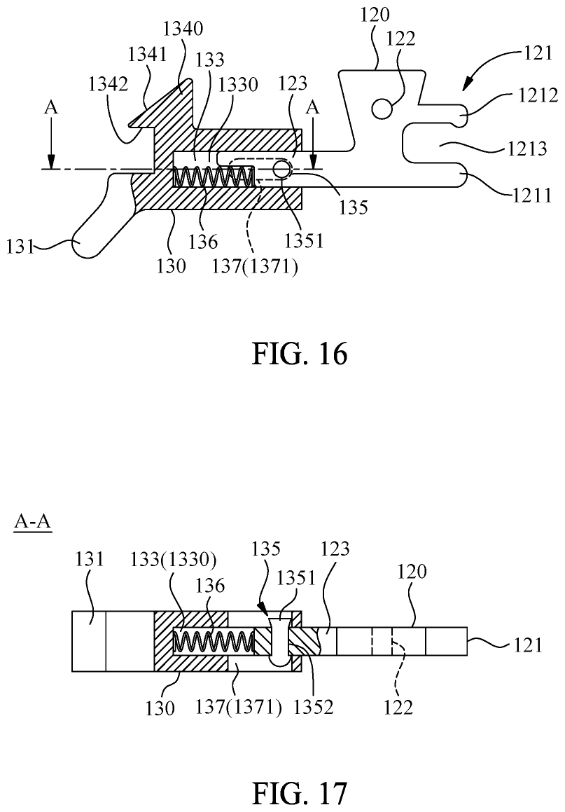

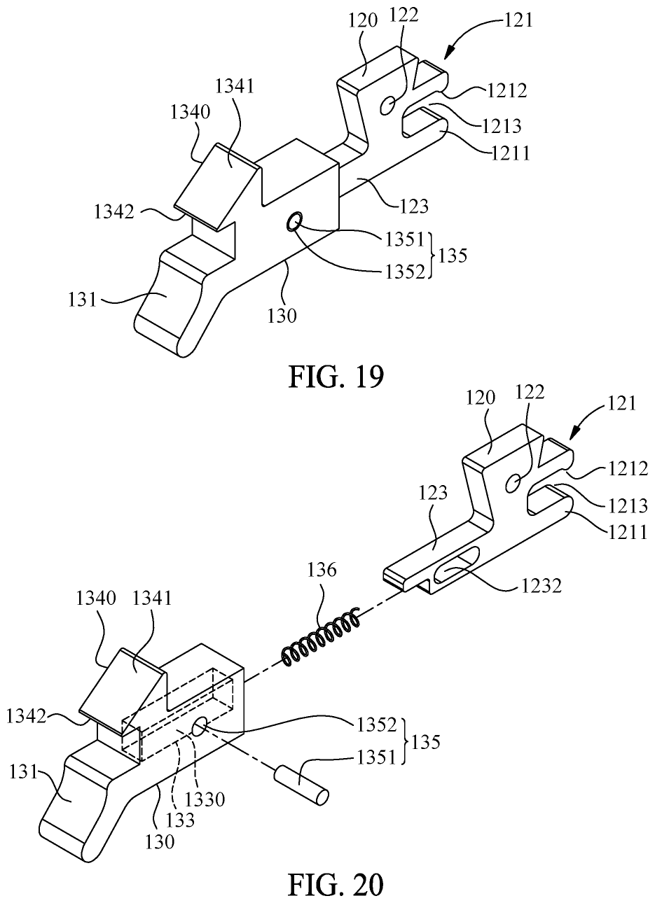

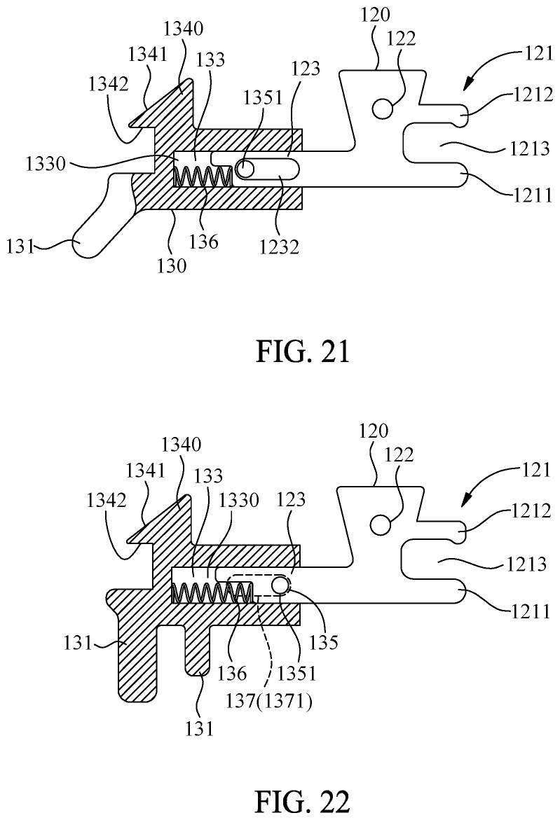

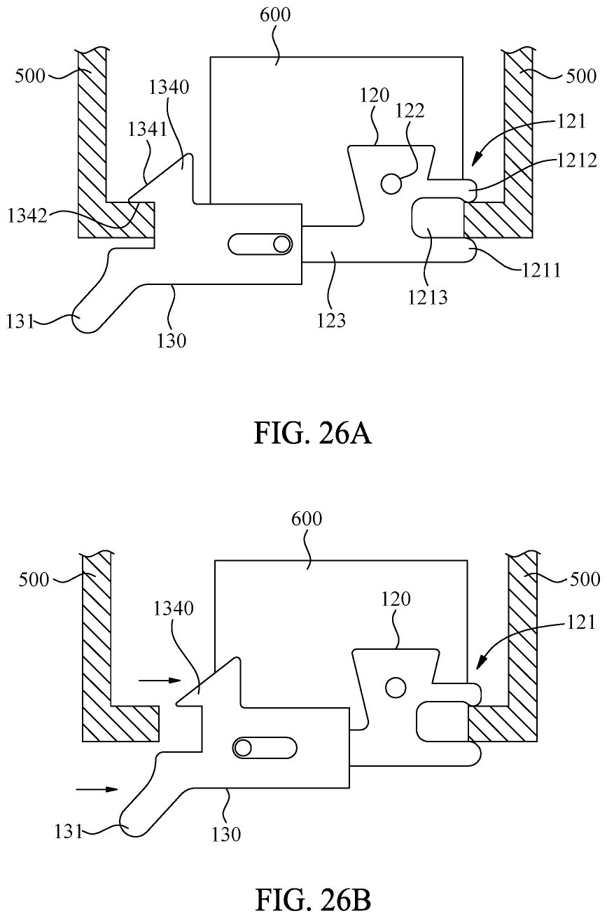

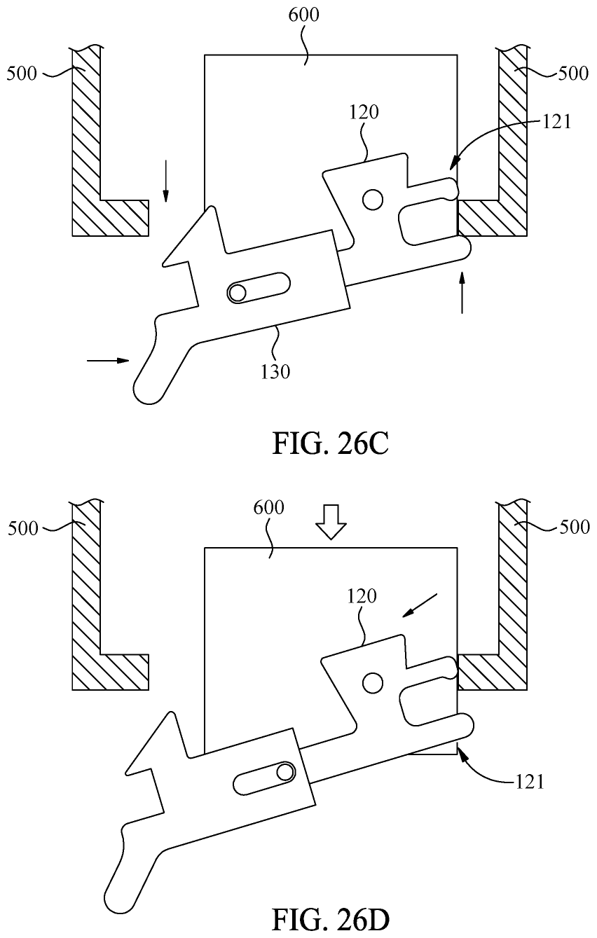

Referring to FIG. 14 through FIG. 22 and FIG. 23 through FIG. 25, as shown in the diagrams, the pull-out aiding device 100 in this embodiment comprises a movable sleeve 130 and a gripping component 120 movably fitted to the movable sleeve 130. The movable sleeve 130 has at least one latch 131, a receiving space 133, and an engaging portion 1340 engaging with a first object 500. The gripping component 120 has an operating portion 123 and a second pivotal connection portion 122 disposed at the operating portion 123. One end of the operating portion 123 is movably coupled to the receiving space 133 of the movable sleeve 130. The second pivotal connection portion 122 is movably coupled to a second object 600 outside the receiving space 133. The latch 131 is a bump formed on any surface of the movable sleeve 130. Referring to FIG. 26B, the movable sleeve 130 is pushed with the latch 131, such that the engaging portion 1340 of the movable sleeve 130 separates from the first object 500, thereby allowing the second object 600 to separate from the first object 500. The pull-out aiding device 100 in this embodiment further comprises a fastening portion 135 which connects the receiving space 133 of the movable sleeve 130 and the operating portion 123 of the gripping component 120; thus, the movable sleeve 130 and the gripping component 120 restrictively move (restrictively slide or restrictively rotate) relative to each other through the fastening portion 135. The pull-out aiding device 100 in this embodiment further comprises a resilient element 136 disposed in the receiving space 133 of the movable sleeve 130 or at any specified point. The resilient element 136 has one end abutting against the receiving space 133 of the movable sleeve 130 and another end abutting against the operating portion 123 of the gripping component 120, such that the movable sleeve 130 and gripping component 120 restrictively move and undergo position restoration relative to each other through the resilient element 136.

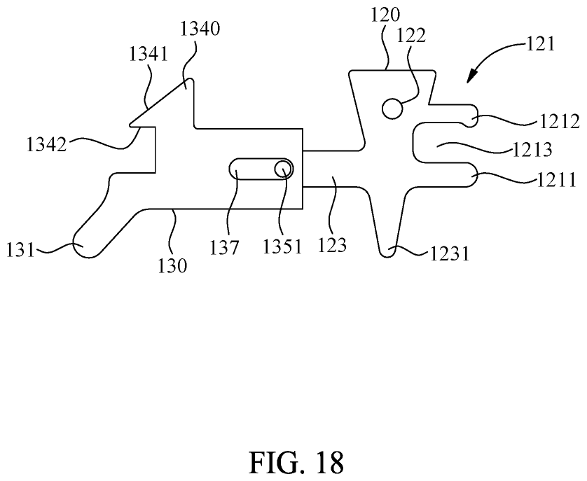

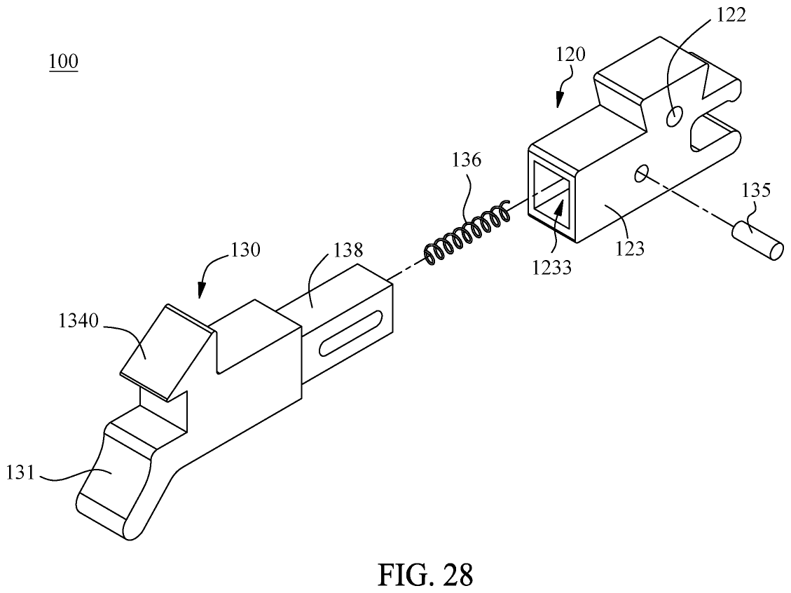

Referring to FIG. 18, the operating portion 123 of the gripping component 120 has a manually-manipulatable portion 1231. The manually-manipulatable portion 1231 is a bump formed at a bottom portion of the operating portion 123 of the gripping component 120. The manually-manipulatable portion 1231 and the latch 131 face the same direction. Referring to FIG. 28, the manually-manipulatable portion 1231 and the latch 131 face downward. A finger (for example, thumb) presses the left side of the latch 131, and another finger (for example, index finger) presses the right side of the manually-manipulatable portion 1231, such that the movable sleeve 130 moves toward the gripping component 120.

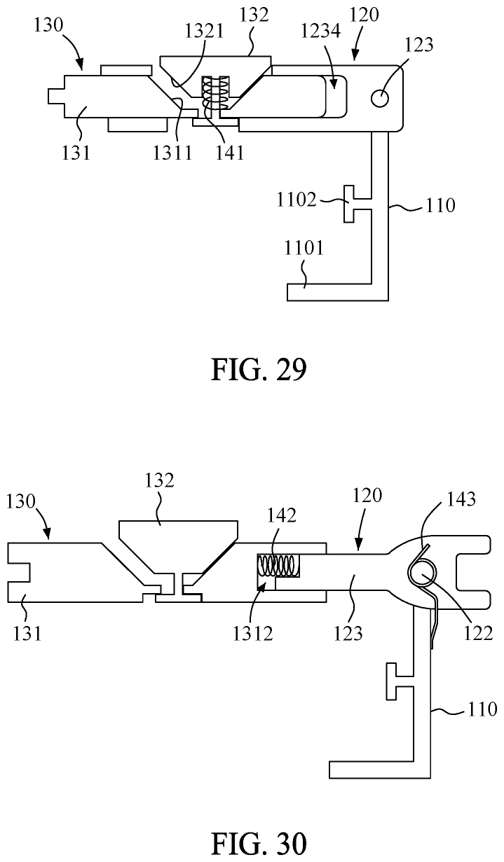

Referring to FIG. 13 and FIG. 14, in this embodiment, the movable sleeve 130 and the gripping component 120 restrictively slide toward each other through the fastening portion 135, such that the engaging portion 1340 and the first object 500 slidingly engage with each other and separate from each other. The movable sleeve 130 has a fastening recess 137 in communication with the receiving space 133, and thus the fastening portion 135 is fastened to the fastening recess 137. The fastening recess 137 is a sliding slot 1371 formed on one or two sidewalls of the receiving space 133; thus, the fastening portion 135 slides in the sliding slot 1371, thereby allowing the movable sleeve 130 and the gripping component 120 to restrictively slide relative to each other. Referring to FIG. 29 through FIG. 31, the operating portion 123 of the gripping component 120 has a sliding oblong hole 1232 in communication with the receiving space 133; thus, the fastening portion 135 slides within the sliding oblong hole 1232 to thereby cause the movable sleeve 130 and the gripping component 120 to restrictively slide relative to each other.

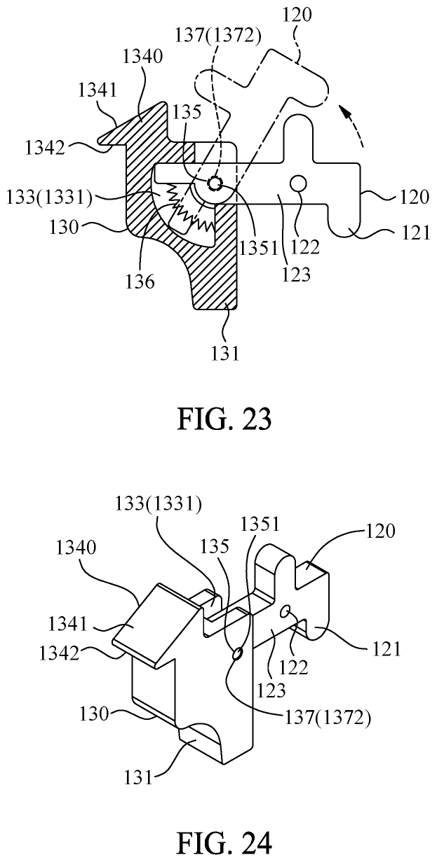

Referring to FIG. 23 through FIG. 25, in this embodiment, the movable sleeve 130 and the gripping component 120 restrictively rotate relative to each other through the fastening portion 135, such that the engaging portion 1340 and the first object 500 rotatably engage with each other and separate from each other. Likewise, the movable sleeve 130 has the fastening recess 137 in communication with the receiving space 133, such that the fastening portion 135 is fastened to the fastening recess 137. However, the fastening recess 137 is a positioning hole 1372 formed on one or two sidewalls of the receiving space 133; thus, the fastening portion 135 rotates within the positioning hole 1372, thereby allowing the movable sleeve 130 and the gripping component 120 to restrictively rotate relative to each other.

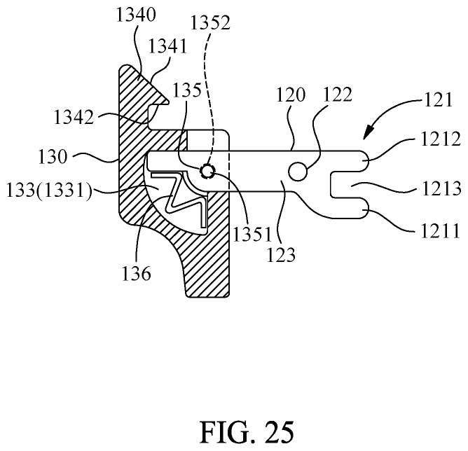

Referring to FIG. 14 and FIG. 15, or FIG. 23 and FIG. 25, according to the present disclosure, the fastening portion 135 is integrally formed with or fitted to a cylinder 1351 of the operating portion 123 of the gripping component 120. Preferably, the operating portion 123 of the gripping component 120 has a fastening hole 1352, and the cylinder 1351 is penetratingly disposed in, engaged with, riveted to, expanded to, adhered to or fastened to the fastening hole 1352. Alternatively, the fastening portion 135 is integrally formed with or fitted to the cylinder 1351 of the movable sleeve 130. Preferably, the operating portion 123 of the gripping component 120 has a fastening hole 1352, and the cylinder 1351 is penetratingly disposed in, engaged with, riveted to, expanded to, adhered to or fastened to the fastening hole 1352. Therefore, the cylinder 1351 is penetratingly disposed in the sliding slot 1371 and slides therein or is penetratingly disposed in the positioning hole 1372 and rotates therein, thereby undergoing restrictive sliding or restrictive rotation. Referring to FIG. 20, according to the present disclosure, the fastening portion 135 is integrally formed with or fitted to the cylinder 1351 of the movable sleeve 130, and the cylinder 1351 penetrates the receiving space 133. Preferably, the movable sleeve 130 has at least one fastening hole 1352 in communication with the receiving space 133, and the cylinder 1351 is penetratingly disposed in, engaged with, riveted to, expanded to, adhered to or fastened to the fastening hole 1352.

Referring to FIG. 14 through FIG. 25, according to the present disclosure, the engaging portion 1340 of the movable sleeve 130 is a left-opening or right-opening hook as shown in the diagrams. The hook is preferably a triangular hook or wedge-shaped hook which protrudes from the movable sleeve 130 and comprises a guiding oblique surface 1341 and a hook surface 1342 connected to the guiding oblique surface 1341, as shown in FIG. 26A. Thus, the first object 500 is pressed inward with the guiding oblique surface 1341 while being engaged with the hook surface 1342.

Referring to FIG. 14 through FIG. 22, according to the present disclosure, the gripping component 120 preferably has at least one U-shaped abutting portion 121 which comprises a first push element 1211 and a second push element 1212 which are formed at one end of the gripping component 120. An engaging recess 1213 is disposed between the first push element 1211 and the second push element 1212. Referring to FIG. 26A, the second push element 1212 and the engaging recess 1213 engage with the first object 500 through the first push element 1211 of the abutting portion 121. Referring to FIG. 26C, to remove the second object 600 easily, the abutting portion 121 pushes the first object 500 by the principle of leverage.

Referring to FIG. 14 through FIG. 22, according to the present disclosure, the second pivotal connection portion 122 of the gripping component 120 is preferably a protruding post integrally formed with the operating portion 123 or a protruding post, engaging post or penetrating hole fitted to the operating portion 123. Referring to FIG. 26A, the protruding post, engaging post or penetrating hole is movably disposed on the second object 600 and is preferably penetratingly disposed in, engaged with, riveted to, expanded to or fastened to the second object 600, such that the pull-out aiding device 100 and the second object 600 can rotate relative to each other.

Referring to FIG. 14 through FIG. 22, according to the present disclosure, the receiving space 133 of the movable sleeve 130 has therein a through-hole-shaped sliding space 1330. One end of the operating portion 123 of the gripping component 120 is penetratingly disposed in the sliding space 1330. The operating portion 123 and the sliding space 1330 are slidingly connected by the fastening portion 135. Therefore, the movable sleeve 130 and the gripping component 120 restrictively slide relative to each other. The resilient element 136 is preferably a helical spring (as shown in FIG. 14 through FIG. 19), leaf spring or resilient cylinder, such that the resilient element 136 has one end abutting against the sliding space 1330 and another end abutting against the operating portion 123, such that the movable sleeve 130 and the gripping component 120 restrictively move and undergo position restoration relative to each other through the resilient element 136.

Referring to FIG. 23 or FIG. 25, according to the present disclosure, the receiving space 133 of the movable sleeve 130 has therein an arcuate sliding space 1331. One end of the operating portion 123 of the gripping component 120 is penetratingly disposed in the sliding space 1331. The operating portion 123 and the sliding space 1331 are rotatably connected by the fastening portion 135. Therefore, the movable sleeve 130 and the gripping component 120 restrictively rotate relative to each other. The resilient element 136 is preferably a helical spring (shown in FIG. 23), leaf spring (as shown in FIG. 25) or resilient cylinder, such that the resilient element 136 has one end abutting against the sliding space 1331 and another end abutting against the operating portion 123; thus, the movable sleeve 130 and the gripping component 120 restrictively move and undergo position restoration relative to each other through the resilient element 136.

According to the present disclosure, the first object 500 is a chassis, casing, drawer cabinet, window frame or any other object, whereas the second object 600 is a circuit board card, drawer, window or any other object. Referring to FIG. 26A, in the first preferred embodiment of the present disclosure, a quick-release rod element is movably fitted to the second object 600 through the second pivotal connection portion 122 of the gripping component 120 and thereby engaged with one side of the first object 500 through the engaging portion 1340 of the movable sleeve 130, whereas the abutting portion 121 of the gripping component 120 is engaged with the other side of the first object 500, such that the second object 600 is slidingly fitted to the first object 500. As shown in FIG. 26B, to remove the second object 600, the user pushes a latch 14 of the movable sleeve 130 by hand, such that the movable sleeve 130 restrictively slides, whereas the engaging portion 1340 separates from the first object 500. As shown in FIG. 26C, the abutting portion 121 of the gripping component 120 pushes the first object 500 by the principle of leverage. Therefore, the second object 600 is slidingly withdrawn. As shown in FIG. 26D, the movable sleeve 130 can undergo position restoration with the resilient element 136, despite separation of the second object 600 and the first object 500 and cessation of exertion of a force on the latch 14.

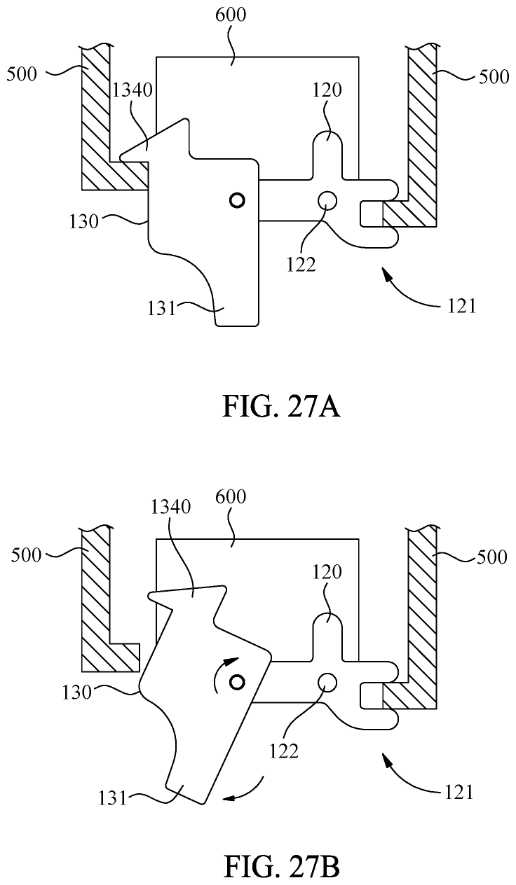

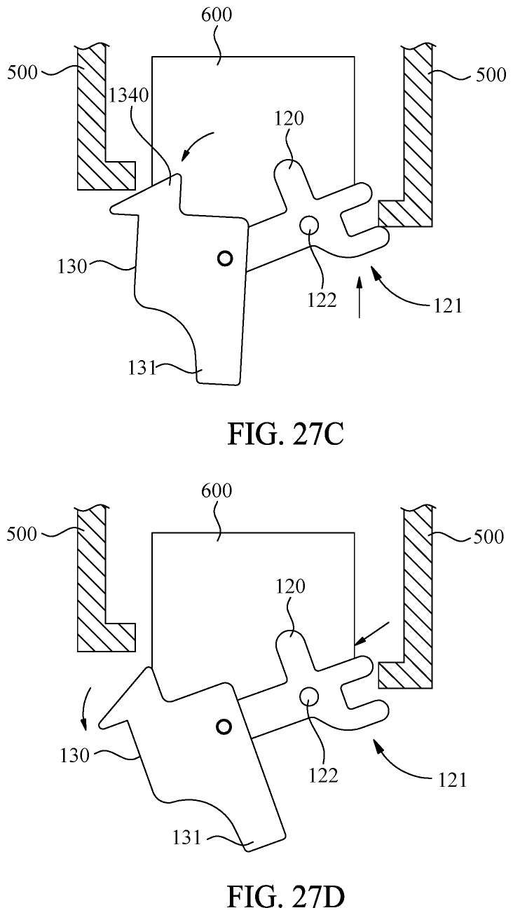

Referring to FIG. 27A, in the fourth preferred embodiment of the present disclosure, likewise, the quick-release rod element is movably fitted to the second object 600 through the second pivotal connection portion 122 of the gripping component 120 and thereby engaged with one side of the first object 500 through the engaging portion 1340 of the movable sleeve 130, whereas the abutting portion 121 of the gripping component 120 is engaged with the other side of the first object 500, such that the second object 600 is slidingly fitted to the first object 500. Referring to FIG. 27B, to remove the second object 600, the user pushes the latch 14 of the movable sleeve 130 by hand, such that the movable sleeve 130 restrictively rotates, whereas the engaging portion 1340 separates from the first object 500. Referring to FIG. 27C, the abutting portion 121 of the gripping component 120 pushes the other side of the first object 500 by the principle of leverage. Therefore, the second object 600 is slidingly withdrawn. Referring to FIG. 27D, the movable sleeve 130 can undergo position restoration with the resilient element 136, despite separation of the second object 600 and the first object 500 and cessation of exertion of a force on the latch 14.

Referring to FIG. 28, the movable sleeve 130 of the pull-out aiding device 100 has a body portion 138, whereas the operating portion 123 of the gripping component 120 has a receiving space 1233 movably coupled to the body portion 138. The receiving space 1233 of the gripping component 120 and the body portion 138 of the movable sleeve 130 are connected by a fastening portion 135. The movable sleeve 130 and the gripping component 120 restrictively move relative to each other through the fastening portion 135. The receiving space 1233 has a resilient element 136. The resilient element 136 has one end abutting against the receiving space 1233 and another end abutting against the body portion 138, such that the movable sleeve 130 and the gripping component 120 restrictively move and undergo position restoration relative to each other through the resilient element 136.

Referring to FIG. 29, in this embodiment, the operating portion 123 of the gripping component 120 has a containing portion 1234. The movable sleeve 130 is movably coupled to the containing portion 1234. The latch 131 of the movable sleeve 130 is movably fitted to a manual push portion 132 of the movable sleeve 130. The latch 131 has a movement surface 1311. The movement surface 1311 abuts against a corresponding movement surface 1321 of the manual push portion 132 to drive the latch 131 moving relative to the containing portion 1234. A resilient element 141 is disposed between the latch 131 and the manual push portion 132. Two ends of the resilient element 141 abut against the latch 131 and the manual push portion 132, respectively. The pulling component 110 has a pulling portion 1101. The pulling portion 1101 pulls a corresponding object (not shown). The pulling component 110 has a fixed connection portion 1102 fixedly connected to the corresponding object.

To start operating the pull-out aiding device, the user presses the manual push portion 132, such that the movement surface 1321 of the manual push portion 132 and the corresponding movement surface 1311 of the latch 131 abut against each other to thereby compress the resilient element 141. Since the movement surface 1321 and the corresponding movement surface 1311 abut against each other, the manual push portion 132 drives the latch 131 moving toward the gripping component 120, such that the receiving space of the containing portion 1234 diminishes (or enlarges) gradually in response to the movement; thus, a portion of the latch 131 enters the containing portion 1234 to thereby drive the latch 131 moving, thereby separating the latch 131 and the second lateral plate. As soon as the user stops pressing the manual push portion 132, the resilient element 141 generates a resilient restoring force under which the latch 131 is pushed to allow the manual push portion 132 to undergo position restoration, such that the latch 131 is latched to the second lateral plate (not shown).

Referring to FIG. 30, in this embodiment, the latch 131 of the movable sleeve 130 has a containing portion 1312, and the operating portion 123 of the gripping component 120 is movably coupled to the containing portion 1312. The latch 131 is movably fitted to a manual push portion 132. The containing portion 1312 has therein a first resilient element 142. Two ends of the first resilient element 142 abut against the latch 131 and the operating portion 123, respectively. The second pivotal connection portion 122 has a second resilient element 143. Two ends of the second resilient element 143 abut against the pulling component 110 and the gripping component 120, respectively.

To start operating the pull-out aiding device, the user presses the manual push portion 132, such that the manual push portion 132 drives the latch 131 moving toward the gripping component 120 to thereby compress the first resilient element 142; thus, a portion of the operating portion 123 moves into the containing portion 1312, thereby separating the latch 131 and the second lateral plate. As soon as the user stops pressing the manual push portion 132, the first resilient element 142 generates a resilient restoring force under which the latch 131 is pushed to allow the manual push portion 132 to undergo position restoration, such that the latch 131 is latched to the second lateral plate. Owing to the movement of the gripping component 120, the second resilient element 143 effects automatic position restoration.

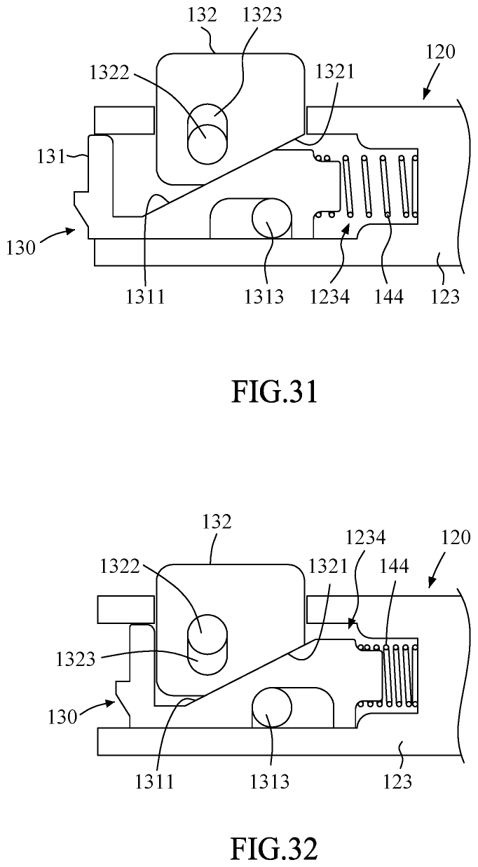

Referring to FIG. 31 and FIG. 32, in this embodiment, the manual push portion 132 of the movable sleeve 130 has a checking portion 1322 and a movable portion 1323 movable by the checking portion 1322. The latch 131 and the operating portion 123 are connected by at least one connecting member 1313. The containing portion 1234 has therein a resilient element 144. Two ends of the resilient element abut against the latch and the operating portion, respectively.

To operate the pull-out aiding device, the user presses the manual push portion 12 downward, such that the manual push portion 12 moves within the containing portion 1234 toward the gripping component 120 because of coordination of the checking portion 1322 and the movable portion 1323, whereas the movement surface 1311 and the corresponding movement surface 1321 abut against each other; hence, the latch 131 moves relative to the connecting member 1313 and compresses the resilient element 22, and thus the manual push portion 12 moves the latch 131 within the containing portion 1234.

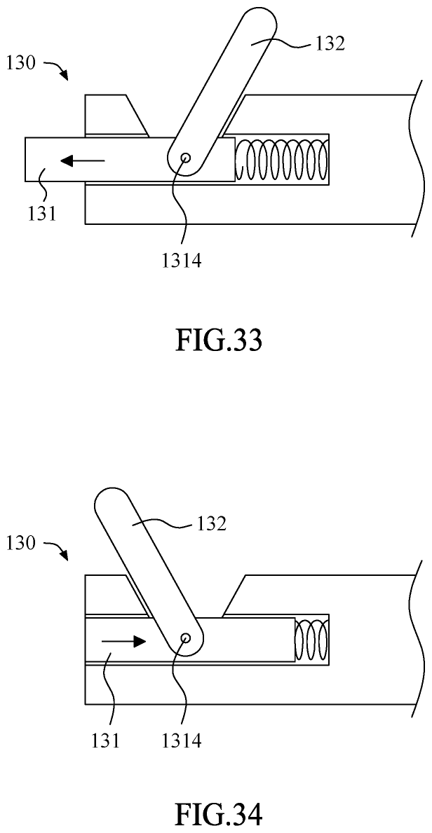

Referring to FIG. 33 and FIG. 34, in this embodiment, a fastening portion 1314 of the latch 131 of the movable sleeve 130 is movably fitted to a manual push portion 132 of the movable sleeve 130. As soon as the user moves the manual push portion 132, the fastening portion 1314 causes the latch 131 to be fastened to or separated from the second lateral plate 220.

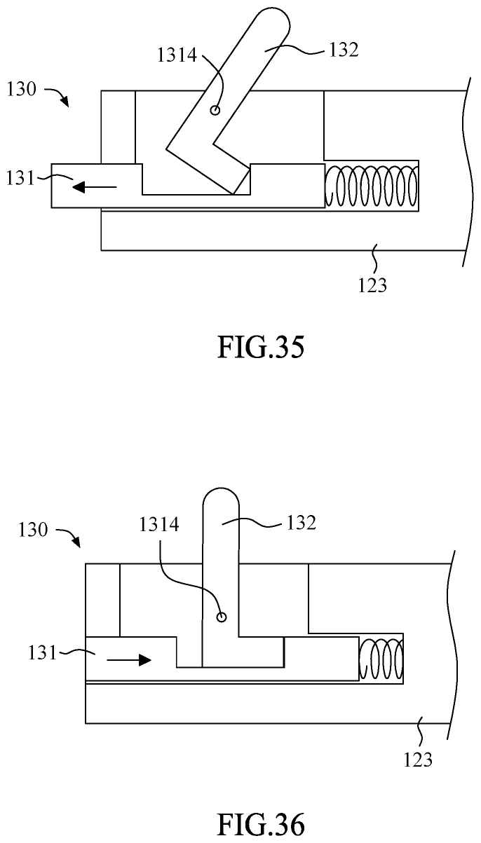

Referring to FIG. 35 and FIG. 36, in this embodiment, the latch 131 of the movable sleeve 130 moves relative to a manual push portion 132 of the movable sleeve 130 and interferes therewith. The manual push portion 132 is movably fitted to the operating portion 123 by a fastening portion 1314; thus, as soon as the user moves the manual push portion 132, the latch 131 is fastened to or separated from the second lateral plate 220.

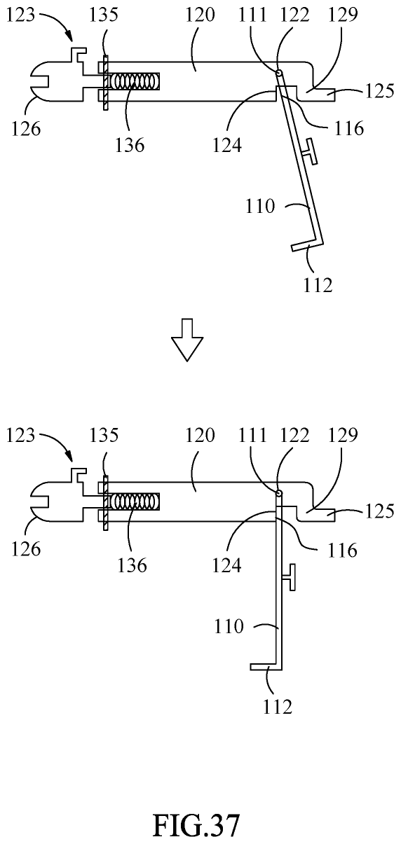

Referring to FIG. 37, in this embodiment, the pulling component 110 further comprises a corresponding obstructing portion 116, whereas the gripping component 120 further comprises an obstructing portion 124. The obstructing portion 124 of the gripping component 120 is obstructed by the corresponding obstructing portion 116 of the pulling component 110 to limit the included angle between the pulling component 110 and the gripping component 120 in operation. The included angle is 90 degrees (or around 90 degrees) or ranges from 70 degrees (or around 70 degrees) to 110 degrees (or around 110 degrees).

In an embodiment, the obstructing portion 124 or the corresponding obstructing portion 116 is a flat surface portion, oblique surface portion, arcuate surface portion, curved surface portion, stepped portion, engaging portion, hook portion, raised portion or dented portion. Therefore, the present disclosure meets practical needs.

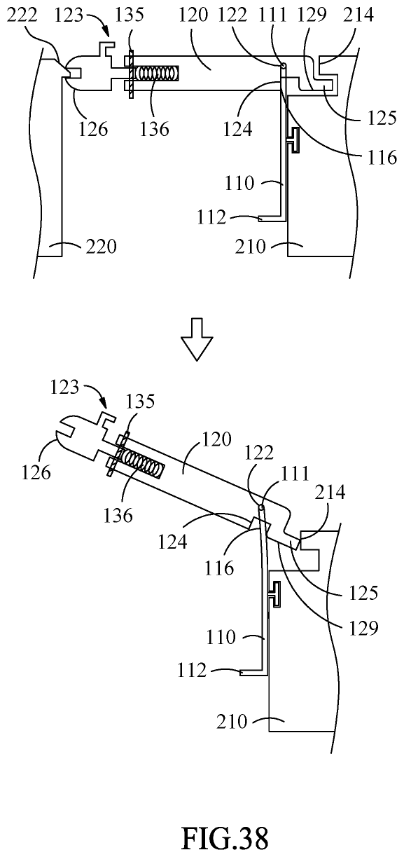

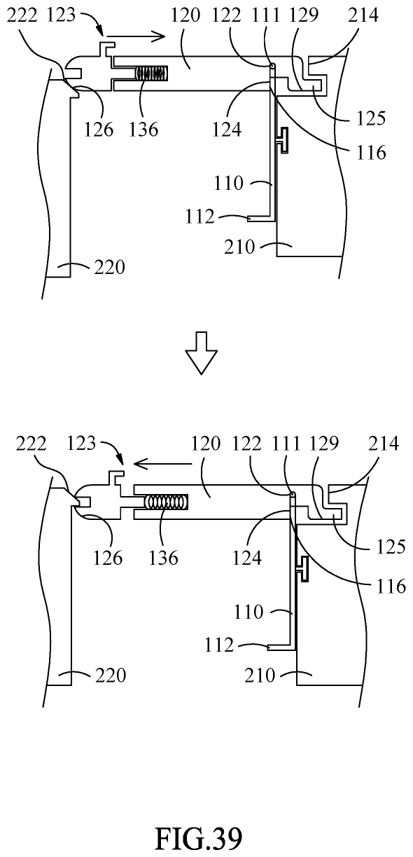

Referring to FIGS. 38 and 39, in this embodiment, the gripping component 120 further comprises a blocking portion 125, whereas the first lateral plate 210 has a corresponding blocking portion 214. The blocking portion 125 of the gripping component 120 and the corresponding blocking portion 214 of the first lateral plate 210 engage with each other to ensure that the return hook portion 129 can engage with an entry position of the first lateral plate 210 only if the gripping component 120 reaches the entry position of the first lateral plate 210 to enable the return hook portion 129 to engage with the first lateral plate 210. Furthermore, the blocking portion 125 of the gripping component 120 and the corresponding blocking portion 214 of the first lateral plate 210 engage with each other to ensure that the blocking portion 214 can enter an entry position of the first lateral plate 210 only if the gripping component 120 reaches a non-blocking position of the first lateral plate 210. In an embodiment, the blocking portion 125 or the corresponding blocking portion 214 is a flat surface portion, oblique surface portion, arcuate surface portion, curved surface portion, stepped portion, engaging portion, hook portion, raised portion or dented portion, such that the present disclosure meets practical needs. In an embodiment, the entry position of the first lateral plate 210 is a flat surface portion, oblique surface portion, arcuate surface portion, curved surface portion, stepped portion, engaging portion, hook portion, raised portion or dented portion, such that the present disclosure meets practical needs. In an embodiment, the blocking portion 125 is the return hook portion 129.

In this embodiment, the gripping component 120 further has a guiding portion 126, and the second lateral plate 220 has a corresponding guiding portion 222. The guiding portion 126 or the corresponding guiding portion 222 is an oblique surface, curved surface, arcuate surface, stepped surface or flat surface. The corresponding guiding portion 222 of the second lateral plate 220 guides the gripping component 120 to resiliently engage with an entry position of the second lateral plate 220. In an embodiment, the entry position of the second lateral plate 220 is a flat surface portion, oblique surface portion, arcuate surface portion, curved surface portion, stepped portion, engaging portion, hook portion, raised portion or dented portion, such that the present disclosure meets practical needs.

In an embodiment, the entry position is a raised portion or dented portion. Therefore, the present disclosure meets practical needs.

While the present disclosure has been described by means of specific embodiments, numerous modifications and variations could be made thereto by those skilled in the art without departing from the scope and spirit of the present disclosure set forth in the claims.

What is claimed is:

1. A pull-out aiding device mountable on an object, the pull-out aiding device comprising:
a pulling component movably or pullably coupled to a first lateral plate and comprising a first pivotal connection portion, a corresponding portion and a corresponding obstructing portion; and
a gripping component comprising a second pivotal connection portion, an operating portion and an obstructing portion, the second pivotal connection portion being pivotally connected to the first pivotal connection portion to allow the gripping component to rotate about the second pivotal connection portion, wherein the obstructing portion of the gripping component is obstructed by the corresponding obstructing portion of the pulling component to limit an included angle between the pulling component and the gripping component.

2. The pull-out aiding device of claim 1, wherein the included angle between the pulling component and the gripping component is 90 degrees or ranges from 70 degrees to 110 degrees.

3. A pull-out aiding device mountable on an object, the pull-out aiding device comprising:
a pulling component movably or pullably coupled to a first lateral plate and comprising a first pivotal connection portion and a corresponding portion, the first lateral plate having a corresponding blocking portion; and
a gripping component comprising a second pivotal connection portion, an operating portion and a blocking portion, the second pivotal connection portion being pivotally connected to the first pivotal connection portion to allow the gripping component to rotate about the second pivotal connection portion, wherein the blocking portion of the gripping component and the corresponding blocking portion of the first lateral plate engage with each other to ensure that the blocking portion can enter an entry position of the first lateral plate only if the gripping component reaches a non-blocking position of the first lateral plate.

4. The pull-out aiding device of claim 3, wherein the gripping component comprises a return hook portion, wherein the blocking portion of the gripping component and the corresponding blocking portion blocking of the first lateral plate engage with each other to ensure that the return hook portion can engage with an entry position of the first lateral plate only if the gripping component reaches the return hook portion to engage with the entry position of the first lateral plate.

5. A pull-out aiding device mountable on an object, the pull-out aiding device comprising:
a pulling component movably or pullably coupled to a first lateral plate and comprising a first pivotal connection portion and a corresponding portion; and
a gripping component comprising a second pivotal connection portion, an operating portion and a guiding portion, the second pivotal connection portion being pivotally connected to the first pivotal connection portion to allow the gripping component to rotate about the second pivotal connection portion, the gripping component alternatively comprising a second lateral plate having a corresponding guiding portion, the corresponding guiding portion guiding the gripping component resilient in engaging with an entry position of the second lateral plate.

6. The pull-out aiding device of claim 1, wherein the obstructing portion or the corresponding obstructing portion is a flat surface portion, oblique surface portion, arcuate surface portion, curved surface portion, stepped portion, engaging portion, hook portion, raised portion or dented portion.

7. The pull-out aiding device of claim 3, wherein the blocking portion or the corresponding blocking portion is a flat surface portion, oblique surface portion, arcuate surface portion, curved surface portion, stepped portion, engaging portion, hook portion, raised portion or dented portion.

8. The pull-out aiding device of claim 3, wherein the entry position of the first lateral plate is a flat surface portion, oblique surface portion, arcuate surface portion, curved surface portion, stepped portion, engaging portion, hook portion, raised portion or dented portion.

9. The pull-out aiding device of claim 5, wherein the entry position of the second lateral plate is a flat surface portion, oblique surface portion, arcuate surface portion, curved surface portion, stepped portion, engaging portion, hook portion, raised portion or dented portion.

10. The pull-out aiding device of claim 3, wherein the blocking portion is a return hook portion.

11. The pull-out aiding device of claim 5, wherein the guiding portion or the corresponding guiding portion is an oblique surface, curved surface, arcuate surface, stepped surface or flat surface.
